(19) United States
(12) Patent Application Publication
(10) Pub. No.: US 2021/0288843 A1
(43) Pub. Date: Sep. 16, 2021

(54) LINEAR EQUALIZATION, AND ASSOCIATED METHODS, DEVICES, AND SYSTEMS

(71) Applicant: Micron Technology, Inc., Boise, ID (US)

(72) Inventors: Won Joo Yun, Boise, ID (US); Jennifer E. Taylor, Boise, ID (US)

(21) Appl. No.: 16/820,461

(22) Filed: Mar. 16, 2020

(51) Int. Cl. H04L 25/03; H03F 3/45; G11C 11/4093

(52) U.S. Cl. CPC H04L 25/03012; H03F 2203/45022; G11C 11/4093; H03F 3/45179

(57) ABSTRACT

Continuous time linear equalization devices are disclosed. A continuous time linear equalization device may include a first circuit including a first differential amplification element coupled to a first adjustable source degeneration element. The continuous time linear equalization device may also include a second circuit having an input coupled to an output of the first circuit and including a second differential amplification element coupled to a second adjustable source degeneration element. Systems are also disclosed.

### TECHNICAL FIELD

Embodiments of the disclosure relate to linear equalization. More specifically, various embodiments relate to continuous time linear equalization, and to related methods, devices, and systems.

### BACKGROUND

Continuous time linear equalization (CTLE) may be used to process signals in various systems and/or devices. For example, in certain memory devices, one or more input buffers may receive data input signals at high speeds, such as speeds of 1 gigabits per second (Gbps) or more. CTLE techniques may then be used to process the input signals (e.g., for conversion into binary bit data). By processing the signals via CTLE techniques, the input buffers may provide for more efficient communication (e.g., with external devices).

### BRIEF DESCRIPTION OF THE DRAWINGS

FIG. 1 is a block diagram of an example memory device, in accordance with at least one embodiment of the present disclosure.

FIG. 2 depicts a curve representing channel loss of a signal, a band curve of a continuous time linear equalization system, and a combined frequency response of the channel loss and the band curve.

FIG. 3A illustrates an example continuous time linear equalization circuit.

FIG. 3B depicts a plot including various gain-versus-frequency curves associated with the continuous time linear equalization circuit of FIG. 3A.

FIG. 4 illustrates another example continuous time linear equalization circuit, in accordance with various embodiments of the present disclosure.

FIG. 5 depicts another plot including various gain-versus-frequency curves associated with the continuous time linear equalization circuit of FIG. 4.

FIGS. 6A-6C depict various simulation results of an input buffer.

FIG. 7 is a flowchart of an example method of operating an input buffer system, in accordance with various embodiments of the present disclosure.

FIG. 8 is a simplified block diagram of a memory system, in accordance with various embodiments of the present disclosure.

FIG. 9 is a simplified block diagram of an electronic system, in accordance with various embodiments of the present disclosure.

### DETAILED DESCRIPTION

Memory devices are typically provided as internal, semiconductor, integrated circuits in computers or other electronic systems. There are many different types of memory including, for example, random-access memory (RAM), read only memory (ROM), dynamic random access memory (DRAM), synchronous dynamic random access memory (SDRAM), resistive random access memory (RRAM), double data rate memory (DDR), low power double data rate memory (LPDDR), phase change memory (PCM), and Flash memory.

Memory devices typically include many memory cells that are capable of holding a charge that is representative of a bit of data. Typically, these memory cells are arranged in a memory array, and data may be written to or retrieved from a memory cell by selectively activating the memory cell via an associated word line driver. Memory devices may store individual bits electronically, wherein the stored bits may be organized into addressable memory elements (e.g., words). To receive and to transmit the bits, the memory devices may include certain data communications circuitry as well as communication lines useful in saving and retrieving the bits from a memory bank. In certain memory devices, input buffers may be used to store data that may be transmitted at high speeds, such as speeds in excess of 1 Gbps.

Input buffers (e.g., of a memory device) may include a continuous time linear equalization (CTLE) system. In certain embodiments, the CTLE system may receive signals representative of input data. The signals may have previously traveled through various interconnects to reach their destination (e.g., input buffer), so any electrical degradation induced at a transmitter, connectors, traces, cabling, and/or a receiver may have an effect on the timing and quality of the signal. For example, waveform distortions in the signal may be caused by impedance mismatches like stubs and vias, frequency dependent attenuation, and electromagnetic coupling between signal traces (e.g., crosstalk). Further, high speed signals moving through a communication channel may be subjected to high frequency impairments such as reflections, dielectric loss, and loss due to a skin effect. These impairments may degrade the quality of the signal making it problematic for a receiver system (e.g., including an input buffer) to interpret the signal data correctly.

The techniques described herein include CTLE devices and/or systems suitable for frequency gain and/or frequency suppression (e.g., in an input buffer). For example, the CTLE devices and/or systems described herein may compensate for loss after a signal travels through a communication channel by restoring frequency content (e.g., via amplification) that may have been lost due to communication channel attenuation. Further, the CTLE devices and/or systems described herein may suppress certain frequencies (e.g., where noise (e.g., noise amplification)) may be of concern. Various CTLE devices and/or systems described herein are configured such that one or more parameters (e.g., a magnitude of a gain peak, a location of the frequency gain, and/or a width of a peak) of a frequency response may be adjustable. By providing for adjustable CTLE devices and/or systems, various embodiments described herein may provide for devices (e.g., input buffers) that may operate in high speed data communications (e.g., over 1 Gbps) in an efficient and flexible manner.

According to various embodiments, as described more fully below, a CTLE device and/or system may include a circuit including a number of adjustable portions (also referred to herein as “stages” or “circuits”). For example, the circuit may include a first adjustable portion (a “first adjustable circuit” or a “first adjustable stage”) including a first differential amplification element coupled to a first adjustable source degeneration element. Further, the circuit may include a second adjustable portion (a “second adjustable circuit” or a “second adjustable stage”) including a second differential amplification element coupled to a second adjustable source degeneration element. According to various embodiments, the second adjustable portion may be coupled to an output of the first adjustable portion. More specifically, in some embodiments, the second differential amplification element (e.g., gates of one or more transistors of the second differential amplification element of the second adjustable portion) may be coupled to the output of the first adjustable portion.

Although various embodiments are described herein with reference to memory devices, the present disclosure is not so limited, and the embodiments may be generally applicable to microelectronic devices that may or may not include semiconductor devices and/or memory devices. Further, although various embodiments described herein include a CTLE device or system within an input butter system, the present disclosure is not so limited, and the embodiments may be generally applicable to CTLE devices and/or systems included within any device, system, or circuit (e.g., optical receivers, graphics circuit, without limitation) that may benefit from adjustable linear equalization. Embodiments of the present disclosure will now be explained with reference to the accompanying drawings.

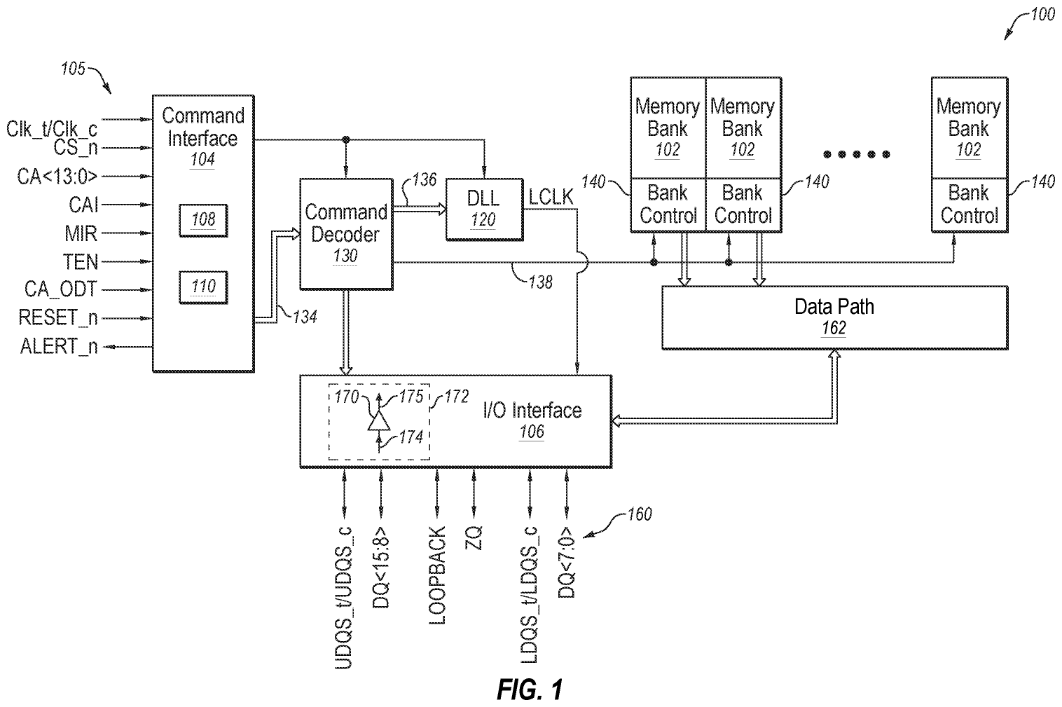

FIG. 1 is a simplified block diagram illustrating certain features of a memory device 100, according to various embodiments of the present disclosure. Specifically, the block diagram of FIG. 1 is a functional block diagram illustrating certain functionality of memory device 100. For example only, memory device 100 may be a double data rate type five synchronous dynamic random access memory (DDR5 SDRAM) device.

Memory device 100 may include a number of memory banks 102, which may be provided on one or more chips (e.g., SDRAM chips) arranged on dual inline memory modules (DIMMS). Each DIMM may include a number of SDRAM memory chips (e.g., x8 or x16 memory chips), as will be appreciated. Each SDRAM memory chip may include one or more memory banks 102. Memory device 100 represents a portion of a single memory chip (e.g., SDRAM chip) having a number of memory banks 102. For DDR5, memory banks 102 may be further arranged to form bank groups. For instance, for an 8 gigabyte (Gb) DDR5 SDRAM, the memory chip may include 16 memory banks 102, arranged into 8 bank groups, each bank group including 2 memory banks. For a 16 Gb DDR5 SDRAM, the memory chip may include 32 memory banks 102, arranged into 8 bank groups, each bank group including 4 memory banks, for instance. Various other configurations, organization and sizes of the memory banks 102 on memory device 100 may be utilized depending on the application and design of the overall system.

Memory device 100 may include a command interface 104 and an input/output (I/O) interface 106. Command interface 104 is configured to provide a number of signals (e.g., signals 105) from an external device (not shown), such as a processor or controller. The processor or controller may provide various signals 105 to memory device 100 to facilitate the transmission and reception of data to be written to or read from memory device 100.

As will be appreciated, command interface 104 may include a number of circuits, such as a clock input circuit 108 and a command address input circuit 110, for instance, to ensure proper handling of signals 105. Command interface 104 may receive one or more clock signals from an external device. Generally, double data rate (DDR) memory utilizes a differential pair of system clock signals, referred to herein as the true clock signal (Clk_t/) and the complementary clock signal (Clk_c). The positive clock edge for DDR refers to the point where the rising true clock signal Clk_t/ crosses the falling complementary clock signal Clk_c, and the negative clock edge indicates that transition of the falling true clock signal Clk_t and the rising of the complementary clock signal Clk_c. Commands (e.g., a read command, a write command, etc.) are typically entered on the positive edges of the clock signal and data is transmitted or received on both the positive and negative clock edges.

Clock input circuit 108 receives true clock signal Clk_t/ and the complementary clock signal Clk_c and generates an internal clock signal CLK. The internal clock signal CLK is supplied to an internal clock generator, such as a delay locked loop (DLL) circuit 120. DLL circuit 120 generates a phase controlled internal clock signal LCLK based on the received internal clock signal CLK. Phase controlled internal clock signal LCLK is supplied to I/O interface 106, for instance, and is used as a timing signal for determining an output timing of read data.

Internal clock signal CLK may also be provided to various other components within memory device 100 and may be used to generate various additional internal clock signals. For instance, internal clock signal CLK may be provided to a command decoder 130. Command decoder 130 may receive command signals from a command bus 134 and may decode the command signals to provide various internal commands. For instance, command decoder 130 may provide command signals to DLL circuit 120 over a command bus 136 to coordinate generation of the phase controlled internal clock signal LCLK. Phase controlled internal clock signal LCLK may be used to clock data through I/O interface 106, for instance.

Further, command decoder 130 may decode commands, such as read commands, write commands, mode-register set commands, activate commands, etc., and provide access to a particular memory bank 102 corresponding to the command, via bus a path 138. As will be appreciated, memory device 100 may include various other decoders, such as row decoders and column decoders, to facilitate access to memory banks 102. In some embodiments, each memory bank 102 includes a bank control 140 block that provides the necessary decoding (e.g., row decoder and column decoder), as well as other features, such as timing control and data control, to facilitate the execution of commands to and from memory banks 102.

Memory device 100 executes operations, such as read commands and write commands, based on the command/address signals received from an external device, such as a processor. The command/address signals are clocked to command interface 104 using the clock signals (Clk_t/and Clk_c). Command interface 104 may include command address input circuit 110, which is configured to receive and transmit the commands to provide access to memory banks 102, through command decoder 130, for instance. In addition, command interface 104 may receive a chip select signal CS_n. Chip select signal CS_n signal enables memory device 100 to process commands on the incoming CA<13:0> bus. Access to specific memory banks 102 within memory device 100 may be encoded on CA<13:0> bus with the commands.

In addition, command interface 104 may be configured to receive a number of other command signals. For instance, a command/address on die termination (CA_ODT) signal may be provided to facilitate proper impedance matching within memory device 100. A reset command (RESET_n) may be used to reset command interface 104, status registers, state machines and the like, during power-up for instance. Command interface 104 may also receive a command/address invert (CAI) signal which may be provided to invert the state of command/address signals CA<13:0> on the command/address bus, for instance, depending on the command/address routing for the particular memory device 100. A mirror (MIR) signal, which may be provided to facilitate a mirror function, may be used to multiplex signals so that they can be swapped for enabling certain routing of signals to memory device 100, based on the configuration of multiple memory devices in a particular application. Various signals to facilitate testing of memory device 100, such as the test enable (TEN) signal, may be provided, as well. For instance, the TEN signal may be used to place memory device 100 into a test mode (e.g., for connectivity testing).

Command interface 104 may also be used to provide an alert signal (ALERT_n) to the system processor or controller for certain errors that may be detected. For instance, an alert signal (ALERT_n) may be transmitted from memory device 100 if a cyclic redundancy check (CRC) error is detected. Other alert signals may also be generated. Further, the bus and pin for transmitting the alert signal (ALERT_n) from memory device 100 may be used as an input pin during certain operations, such as the connectivity test mode executed using the TEN signal, as described above.

Data for read and write commands may be sent to and from memory device 100, utilizing the command and clocking signals discussed above, by transmitting and receiving data signals 160 through I/O interface 106. More specifically, data may be sent to or retrieved from memory banks 102 over data path 162, which includes a plurality of bi-directional data buses. Data IO signals, generally referred to as DQ signals, are generally transmitted and received in one or more bi-directional data buses. For certain memory devices, such as a DDR5 SDRAM memory device, the IO signals may be divided into upper and lower bytes. For instance, for a x16 memory device, the IO signals may be divided into upper and lower IO signals (e.g., DQ<15:8> and DQ<7:0>) corresponding to upper and lower bytes of the data signals, for instance.

The data (e.g., IO signals) for read and writes may be addressed to certain memory (e.g., memory cells) in memory banks 102. The techniques described herein provide for a continuous time linear equalization (CTLE) system (also referred to herein as “CTLE device”) 170 that may process input signals (e.g., DQ<15:8> and DQ<7:0>) received via I/O interface 106. CTLE system 170 may be included in, for example, an input buffer system 172. Incoming signals may be processed by CTLE system 170 to provide both frequency gain and frequency suppression in input buffer system 172.

For example, CTLE system 170 may compensate for loss after a signal travels through a communication channel 174 by amplifying the received signal, thus restoring frequency content that may have been lost due to the communication channel attenuation. CTLE system 170 may additionally suppress certain frequencies (e.g., where noise (e.g., noise amplification) may be of concern). For example, CTLE system 170 may adjust a magnitude of a gain peak, a location of frequency gain, and/or a width of a peak. The signal processed by CTLE system 170 may then be provided to other components or systems of input buffer system 172 via, for example, a communication channel 175. Although CTLE system 170 is depicted as disposed in input buffer system 172, CTLE system 170 may be disposed in any system that may benefit from amplification and/or frequency suppression or filtering, such as optical receivers, graphics circuitry, and so on. Signals received and processed by CTLE system 170 may be more flexibly adjusted, as further described below.

An impedance (ZQ) calibration signal may also be provided to memory device 100 through I/O interface 106. The ZQ calibration signal may be provided to a reference pin and used to tune output drivers and ODT values by adjusting pull-up and pull-down resistors of memory device 100 across changes in process, voltage and temperature (PVT) values. Because PVT characteristics may impact the ZQ resistor values, the ZQ calibration signal may be provided to the ZQ reference pin to be used to adjust the resistance to calibrate the input impedance to known values. As will be appreciated, a precision resistor is generally coupled between the ZQ pin on memory device 100 and GND/VSS external to memory device 100. The precision resistor may act as a reference for adjusting internal ODT and drive strength of the 10 pins.

In addition, a loopback signal (LOOPBACK) may be provided to memory device 100 through I/O interface 106. The loopback signal may be used during a test or debugging phase to set memory device 100 into a mode wherein signals are looped back through memory device 100 through the same pin. For instance, the loopback signal may be used to set memory device 100 to test the data output (DQ) of memory device 100. Loopback may include both a data and a strobe or possibly just a data pin. This is generally intended to be used to monitor the data captured by memory device 100 at I/O interface 106.

As will be appreciated, various other components such as power supply circuits (for receiving external VDD and VSS signals), mode registers (e.g., to define various modes of programmable operations and configurations), read/write amplifiers (e.g., to amplify signals during read/write operations), temperature sensors (e.g., for sensing temperatures of the memory device 100), etc., may also be incorporated into memory device 100. Accordingly, it should be understood that the block diagram of FIG. 1 is only provided to highlight certain functional features of memory device 100 to aid in the subsequent detailed description. For example, CTLE system 170 or certain circuitry of CTLE system 170 may be disposed as part of one bank control 140 or all bank controls 140, as part of one memory bank 102 or all memory banks 102, or combinations thereof.

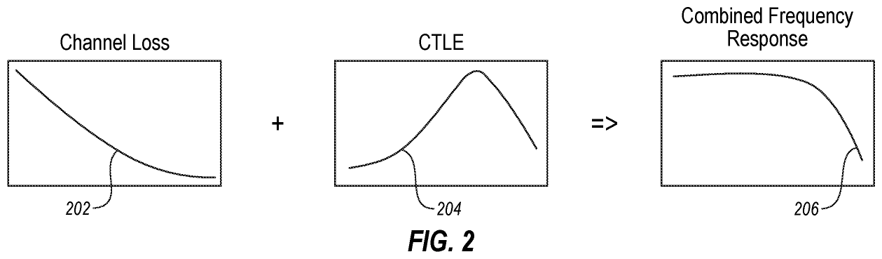

FIG. 2 depicts a curve 202 representing channel loss of a signal (e.g., at an interface, such as a memory device interface), and a band curve 204 of a CTLE system. As will be appreciated, combining curve 202 and band curve 204 may provide a combined frequency response 206.

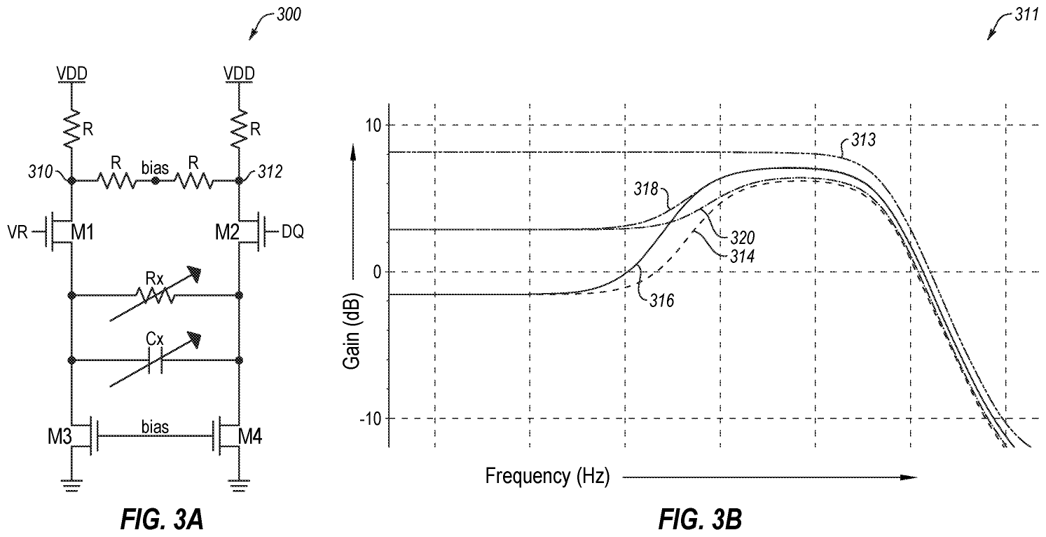

FIG. 3A depicts a CTLE circuit 300 (e.g., of a CTLE system) that includes amplification and resistance-capacitance (RC) source degeneration. CTLE circuit 300 includes an amplification stage (i.e., including amplification elements (e.g., MOSFET transistors M1 and M2)), and adjustable RC elements (i.e., a variable resistor Rx and a variable capacitor Cx). More specifically, CTLE circuit 300 includes a transistor M1 having a gate coupled to a voltage reference VR, and a transistor M2 having a gate coupled to a DQ input signal (e.g., DQ<15:8> and DQ<7:0>). A voltage source (VDD) may be coupled to resistors R to provide for operating power. As depicted, resistors R are coupled to drains of transistors M1 and M2. Additionally, sources of transistors M1 and M2 are coupled to resistor Rx and capacitor Cx. CTLE circuit 300 further includes bias elements or current source elements (e.g., MOSFET transistors M3 and M4) to establish a predetermined or desired current flow. Transistors M1 and M2, collectively or individually, may be referred to as a differential amplifier element, and the adjustable RC elements (i.e., resistor Rx and capacitor Cx), collectively or individually, may be referred to as a source degeneration element.

As input signal DQ is gated through amplification element M2, input signal DQ may be amplified and filtered, for example, to remove intersymbol interference (ISI). ISI may be caused by high frequency amplitude and phase distortion which may “smear” the data bits at the receiving side. Output for CTLE circuit 300 may then be connected to nodes 310, 312. In other words, CTLE circuit 300 includes a differential output including a first output at node 310 and a second output at node 312. For example, communication channel 175 of FIG. 1 may be connected to nodes 310, 312.

Via testmodes and/or fuses, adjusting variable resistor Rx and/or variable capacitor Cx may provide a flexible AC gain curve to compensate channel loss in various external environments In conventional CTLE devices, equalizer gain is based on DC gain (i.e., equalizer gain=peak gain−DC gain), and to increase the equalizer gain at high frequency, the DC gain may be decreased by increasing a value of variable resistor Rx. Further, to exhibit sufficient DC gain and equalizer gain, the DC gain of the amplification stage (including transistors M1 and M2) (i.e., when CTLE is disabled) should be high enough, which may undesirably decrease a bandwidth of CTLE circuit 300.

FIG. 3B includes a plot 311 depicting curves (e.g., gain-versus-frequency curves) 313, 314, 316, 318, and 320 plotted in a frequency domain. Plot 311 includes an X-axis having an increasing frequency and a Y-axis having an increasing gain in decibels (dB). Curve 313 represents an example frequency response without CTLE, and curves 314, 316, 318, and 320 represent example frequency responses utilizing CTLE. More specifically, curves 314, 316, 318, and 320 represent example frequency responses with various values for RC elements (i.e., resistor Rx and capacitor Cx). As will be appreciated, various frequency responses may be achieved via various resistance/capacitance combinations of resistor Rx and capacitor Cx. For example, increasing a resistance of resistor Rx may decrease a DC gain, and increasing a capacitance of capacitor Cx may move a peak value to a lower frequency. As will be further appreciated, peak gain increment may be achieved via decreasing the DC gain by increasing resistor Rx. Further, at some frequencies, CTLE circuit 300 may increase the gain, which may undesirably amplify unwanted noise.

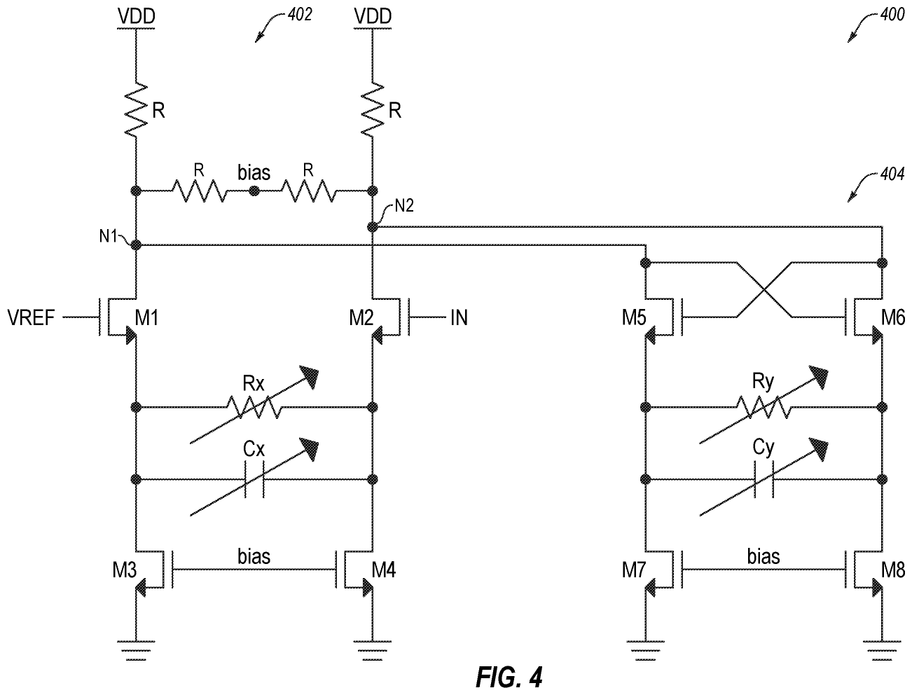

FIG. 4 is an example circuit 400, in accordance with various embodiments of the present disclosure. Circuit 400, which may include or may be part of a CTLE system and/or device, includes a first portion (also referred to herein as a “adjustable portion” “adjustable stage,” “stage,” “adjustable circuit,” or simply “circuit”) 402 and a second portion (also referred to herein as a “adjustable portion” “adjustable stage,” “stage,” “adjustable circuit,” or simply “circuit”) 404. For example, circuit 400 may be part of a CTLE device (e.g., CTLE system 170 of FIG. 1) and/or an input buffer system (e.g., input buffer system 172 of FIG. 1). As described more fully herein, circuit 400 may be configured to adjust a frequency amplification and/or a frequency suppression of a received signal.

First portion 402 of circuit 400 includes resistors R, an amplification element (i.e., differential amplification element including transistors M1 and M2), and a source degeneration element (i.e., including variable resistor Rx and variable capacitor Cx). Voltage source (VDD) may be coupled to resistors R to provide for operating power. First portion 402 further includes bias elements or current source elements (e.g., transistors M3 and M4) to establish a predetermined or desired current flow.

A node N1, which may be a first differential output of circuit 400, may be coupled to a first terminal (e.g., a drain) of transistor M1. A second terminal (e.g., a source) of transistor M1 may be coupled to the source degeneration element including resistor Rx and capacitor Cx. The second terminal of transistor M1 may also be coupled to a first terminal (e.g., a drain) of transistor M3. A third terminal (e.g., a gate) of transistor M1 is configured to receive a reference voltage VREF. A second terminal (e.g., a source) of transistor M3 is configured to couple to a reference voltage (e.g., a ground voltage), and a third terminal (e.g., a gate) of transistor M3 is configured to receive a bias voltage.

A node N2, which may be a second differential output of circuit 400, may be coupled to a first terminal (e.g., a drain) of transistor M2. A second terminal (e.g., a source) of transistor M2 may be coupled to the source degeneration element including resistor Rx and capacitor Cx. The second terminal of transistor M2 may also be coupled to a first terminal (e.g., a drain) of transistor M4. A third terminal (e.g., a gate) of transistor M2 is configured to receive an input voltage IN (e.g., DQ input signal (e.g., DQ<15:8> and DQ<7:0>)). A second terminal (e.g., a source) of transistor M4 is configured to couple to a reference voltage (e.g., a ground voltage), and a third terminal (e.g., a gate) of transistor M4 is configured to receive the bias voltage.

Second portion 404 of circuit 400 includes an amplification element (i.e., a differential amplification element including transistors M5 and M6), and a source degeneration element (i.e., including a variable resistor Ry and a variable capacitor Cy). Second portion 404 further includes bias elements or current source elements (e.g., transistors M7 and M8) to establish a predetermined or desired current flow.

Node N1 is coupled to a first terminal (e.g., a drain) of transistor M5. A second terminal (e.g., a source) of transistor M5 is coupled to the source degeneration element including resistor Ry and capacitor Cy. The second terminal of transistor M5 is also coupled to a first terminal (e.g., a drain) of transistor M7, and a third terminal (e.g., a gate) of transistor M5 is coupled to node N2. A second terminal (e.g., a source) of transistor M7 is configured to couple to a reference voltage (e.g., a ground voltage), and a third terminal (e.g., a gate) of transistor M7 is configured to receive a bias voltage.

Node N2 is coupled to a first terminal (e.g., a drain) of transistor M6. A second terminal (e.g., a source) of transistor M6 may be coupled to the source degeneration element including resistor Ry and capacitor Cy. The second terminal of transistor M6 is also coupled to a first terminal (e.g., a drain) of transistor M8. A third terminal (e.g., a gate) of transistor M6 is coupled to node N1. Further, a second terminal (e.g., a source) of transistor M8 is configured to couple to a reference voltage (e.g., a ground voltage), and a third terminal (e.g., a gate) of transistor M8 is configured to receive the bias voltage.

As will be appreciated, the output of first portion 402 (i.e., N1 and N2), which is also the output of circuit 400, is coupled to second portion 404, wherein second portion 404 includes cross coupled switches (e.g., NMOS transistors). Stated another way, transistor M5 has a gate coupled to a differential output of circuit 400 (i.e., node N2) and a drain coupled to another differential output of circuit 400 (i.e., node N1), and transistor M6 has a gate coupled to a differential output of circuit 400 (i.e., node N1) and a drain coupled to another differential output of circuit 400 (i.e., node N2).

According to various embodiments, one or more performance (“response”) parameters (e.g., a DC gain, a peaking gain, and/or a peaking frequency) of a response of circuit 400 may be set via adjusting variable resistor Rx, variable resistor Ry, variable capacitor Cx, and/or variable capacitor Cy. More specifically, via adjusting first portion 402 (i.e., adjusting variable resistor Rx and/or variable capacitor Cx) and/or second portion 404 (i.e., adjusting variable resistor Ry and/or variable capacitor Cy), a DC gain, a peaking gain, a high-frequency gain, and/or a bandwidth of a response of circuit 400 may be set. Stated another way, adjustable portions 402 and 404 provide flexibility to adjust various response parameters of circuit 400. According to some embodiments, high-frequency peaking may be achieved without substantially degrading a lower frequency gain and/or a bandwidth of circuit 400.

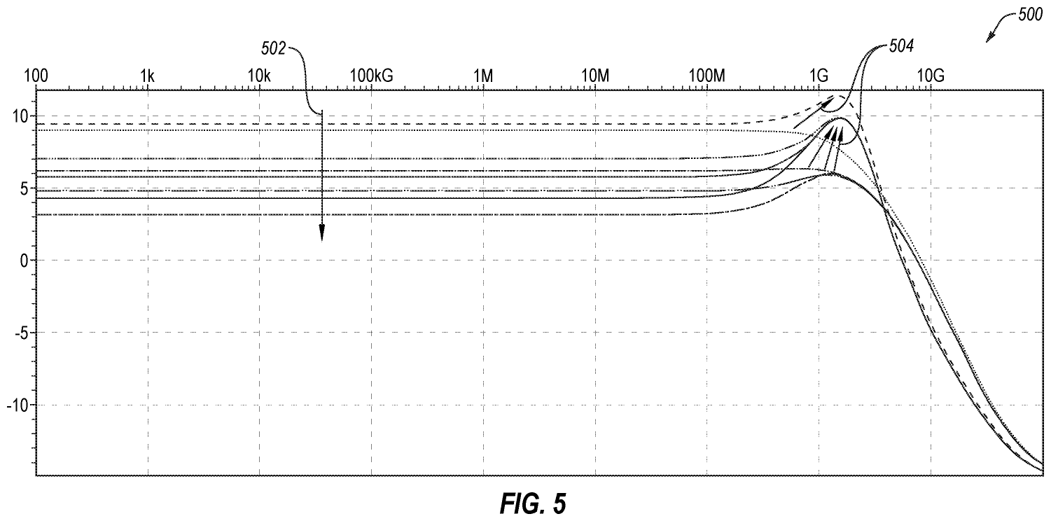

FIG. 5 depicts a plot 500 depicting a number of curves (e.g., gain-versus-frequency curves) plotted in the frequency domain and generated via a CTLE device (e.g., including circuit 400 of FIG. 4), according to one or more embodiments of the present disclosure. Plot 500 includes an X-axis having an increasing frequency and a Y-axis having an increasing gain in decibels (dB). According to various embodiments, increasing a value of resistor Rx and/or resistor Ry of circuit 400 of FIG. 4 may decrease a gain (e.g., as shown via arrow 502), and increasing a value of capacitance Cx and/or capacitance Cy of circuit 400 may reduce a frequency of a peak of a response (e.g., from greater than 1 GHz to less than 1 GHz). Further, according to some embodiments, increasing a value of capacitance Cy may increase a gain of a peak (e.g., as shown via arrows 504) of a response.

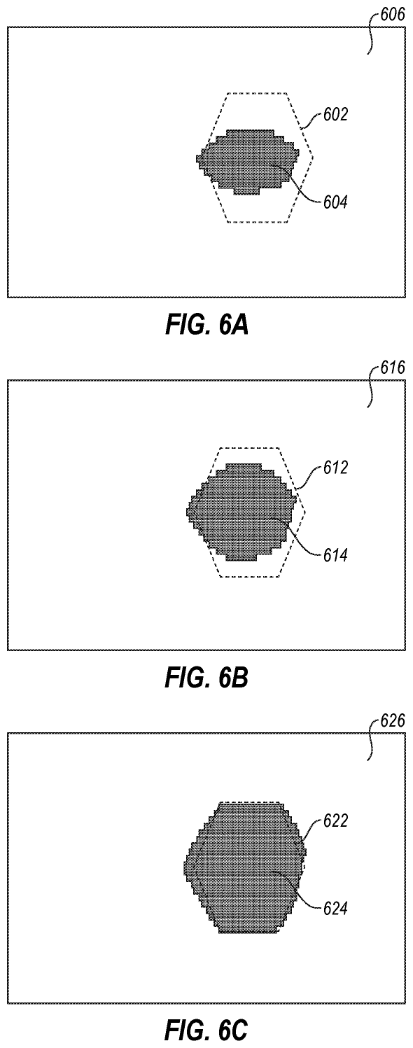

FIGS. 6A-6C depict various simulation results associated with an input buffer system. More specifically, FIG. 6A depicts an input signal mask 602, a pass region 604 and a fail region 606 for an input buffer without CTLE. Further, FIG. 6B depicts an input signal mask 612, a pass region 614 and a fail region 616 for an input buffer with a conventional CTLE device (e.g., including CTLE circuit 300 of FIG. 3A). Moreover, FIG. 6C depicts an input signal mask 622, a pass region 624 and a fail region 626 for an input buffer including a CTLE device, such as a CTLE device including circuit 400 of FIG. 4. As will be understood by a person having ordinary skill in the art, a two-stage CTLE device (e.g., including circuit 400 of FIG. 4), in accordance with various embodiments, allows for flexible bandwidth shaping, and thus improved performance (i.e., compared to a conventional CTLE device).

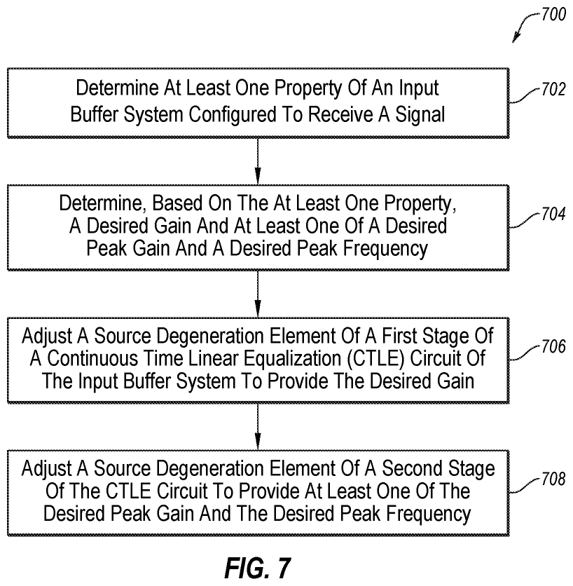

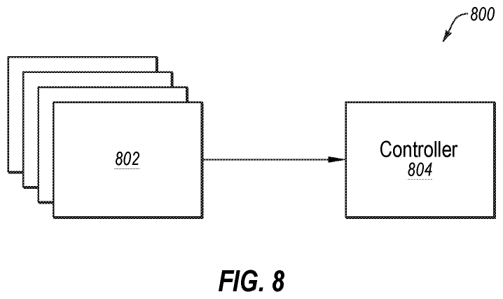

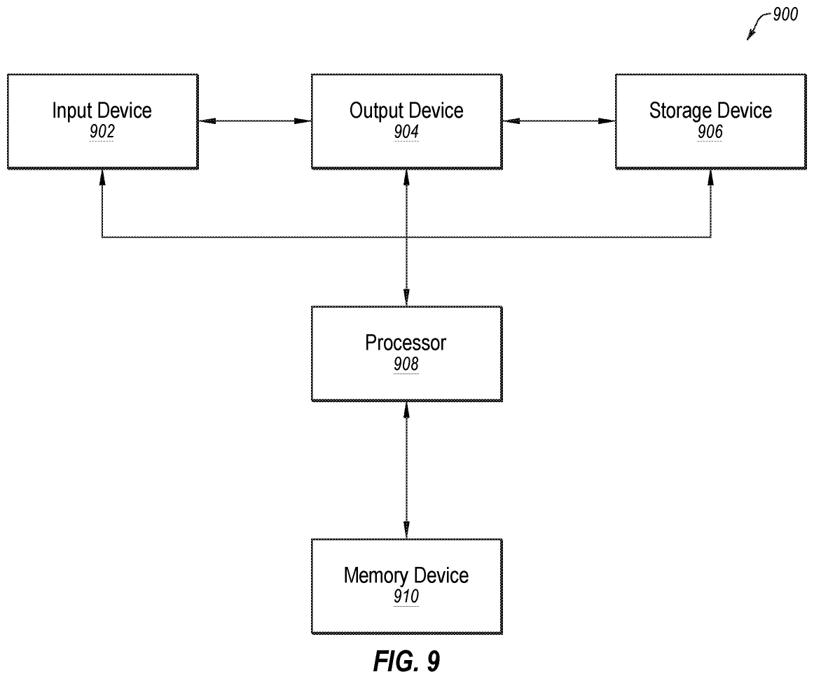

FIG. 7 is a flowchart of an example method 700 of operating an input buffer system, in accordance with various embodiments of the disclosure. Method 700 may be arranged in accordance with at least one embodiment described in the present disclosure. Method 700 may be performed, in some embodiments, by a device or system, such as memory device 100 of FIG. 1, circuit 400 of FIG. 4, a memory system 800 of FIG. 8, and/or an electronic system 900 of FIG. 9, or another device or system. Although illustrated as discrete blocks, various blocks may be divided into additional blocks, combined into fewer blocks, or eliminated, depending on the desired implementation.

Method 700 may begin at block 702, wherein at least one property of an input buffer system configured to receive a signal may be determined, and method 700 may proceed to block 704. For example, a frequency of input buffer system 172 (see FIG. 1), a desired data transmission rate of input buffer system 172, and/or one or more physical properties of communication channels 174, 175 (see FIG. 1) (e.g., properties of a conductor and/or dielectric (e.g., type, length, material, etc.) may be determined.

At block 704, a desired gain and at least one of a desired peak gain and a desired peak frequency may be determined based on the at least one property, and method 700 may proceed to block 706.

At block 706, a source degeneration element of a first stage of a CTLE circuit of the input buffer system may be adjusted to provide the desired gain, and method 700 may proceed to block 708. For example, variable resistor Rx and/or variable capacitor Cx of first portion 402 of circuit 400 (see FIG. 4) may be adjusted to provide the desired gain.

At block 708, a source degeneration element of a second stage of the CTLE circuit may be adjusted to provide at least one of the desired peak gain and the desired peak frequency. For example, variable resistor Ry and/or variable capacitor Cy of second portion 404 of circuit 400 (see FIG. 4) may be adjusted to provide the desired peak gain, the desired peak frequency, or both. According to some embodiments, an output of the first stage of the CTLE circuit, which may also be an output of the CTLE circuit, is coupled to an input of the second stage of the CTLE circuit.

Modifications, additions, or omissions may be made to method 700 without departing from the scope of the present disclosure. For example, the operations of method 700 may be implemented in differing order. Furthermore, the outlined operations and actions are only provided as examples, and some of the operations and actions may be optional, combined into fewer operations and actions, or expanded into additional operations and actions without detracting from the essence of the disclosed embodiment. For example, a method may include one or more acts wherein signal is received at the input buffer system. Further, a method may include one or more acts wherein the received signal is processed via the input buffer system to provide a desired response (e.g., a desired gain, a desired peak gain, and/or a desired peak frequency).

A memory system is also disclosed. According to various embodiments, the memory system may include a controller and a number of memory devices. Each memory device may include one or more memory cell arrays, which may include a number of memory cells.

FIG. 8 is a simplified block diagram of a memory system 800 implemented according to one or more embodiments described herein. Memory system 800, which may include, for example, a semiconductor device, includes a number of memory devices 802 and a controller 804. For example, at least one memory device 802 may include one or more input buffer systems and/or one or more CTLE devices and/or systems, as described herein. Controller 804 may be operatively coupled with memory devices 802 so as to convey command/address signals to memory devices 802.

An electronic system is also disclosed. According to various embodiments, the electronic system may include a memory device including a number of memory dies, each memory die having an array of memory cells. Each memory cell may include an access transistor and a storage element operably coupled with the access transistor.

FIG. 9 is a simplified block diagram of an electronic system 900 implemented according to one or more embodiments described herein. Electronic system 900 includes at least one input device 902, which may include, for example, a keyboard, a mouse, or a touch screen. Electronic system 900 further includes at least one output device 904, such as a monitor, a touch screen, or a speaker. Input device 902 and output device 904 are not necessarily separable from one another. Electronic system 900 further includes a storage device 906. Input device 902, output device 904, and storage device 906 may be coupled to a processor 908. Electronic system 900 further includes a memory device 910 coupled to processor 908. Memory device 910 may include memory system 800 of FIG. 8. Electronic system 900 may include, for example, a computing, processing, industrial, or consumer product. For example, without limitation, electronic system 900 may include a personal computer or computer hardware component, a server or other networking hardware component, a database engine, an intrusion prevention system, a handheld device, a tablet computer, an electronic notebook, a camera, a phone, a music player, a wireless device, a display, a chip set, a game, a vehicle, or other known systems.

Various embodiments of the present disclosure may include a device. The device may include a first circuit including a first differential amplification element coupled to a first adjustable source degeneration element. The device may also include a second circuit having an input coupled to an output of the first circuit and including a second differential amplification element coupled to a second adjustable source degeneration element.

According to another embodiment of the present disclosure, a system may include a first adjustable stage including a first amplification stage coupled to a first source degeneration element. The system may also include a second adjustable stage including second amplification stage coupled to a second source degeneration element. The second amplification stage having a first input and a second input, wherein each of the first input and the second input of the second amplification stage are coupled to each of a first output and a second output of a differential output of the first adjustable stage

Additional embodiments of the present disclosure include an electronic system. The electronic system may include at least one input device, at least one output device, and at least one processor device operably coupled to the input device and the output device. The electronic system may also include at least one memory device operably coupled to the at least one processor device and comprising at least one input buffer. The at least one input buffer may include a first stage including a first amplification stage coupled to a first source degeneration element. Further, the at least one input buffer may also include a second stage including second amplification stage coupled to a second source degeneration element. The second amplification stage may include a first transistor having a first terminal coupled to the first output of the first stage, a second terminal coupled to the second source degeneration element, and a third terminal coupled to the second output of the first stage. The second amplification stage may also include a second transistor having a first terminal coupled to the second output of the first stage, a second terminal coupled to the second source degeneration element, and a third terminal coupled to the first output of the first stage.

In accordance with common practice, the various features illustrated in the drawings may not be drawn to scale. The illustrations presented in the present disclosure are not meant to be actual views of any particular apparatus (e.g., device, system, etc.) or method, but are merely idealized representations that are employed to describe various embodiments of the disclosure. Accordingly, the dimensions of the various features may be arbitrarily expanded or reduced for clarity. In addition, some of the drawings may be simplified for clarity. Thus, the drawings may not depict all of the components of a given apparatus (e.g., device) or all operations of a particular method.

As used herein, the term “device” or “memory device” may include a device with memory, but is not limited to a device with only memory. For example, a device or a memory device may include memory, a processor, and/or other components or functions. For example, a device or memory device may include a system on a chip (SOC).

As used herein, the term “semiconductor” should be broadly construed, unless otherwise specified, to include microelectronic and MEMS devices that may or may not employ semiconductor functions for operation (e.g., magnetic memory, optical devices, etc.).

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. As used herein, “and/or” includes any and all combinations of one or more of the associated listed items.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms first,” “second,” “third,” etc., connote a specific number of elements, these terms should not be understood to connote a specific number of elements.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternative useful combinations of the elements described, will become apparent to those skilled in the art from the description. Such modifications and embodiments also fall within the scope of the appended claims and equivalents.

1. A device, comprising:
a first circuit including a first differential amplification element coupled to a first adjustable source degeneration element; and
a second circuit having an input coupled to an output of the first circuit and including a second differential amplification element coupled to a second adjustable source degeneration element, the second adjustable source degeneration element comprising an adjustable resistor and an adjustable capacitor coupled in parallel with the adjustable resistor.

2. The device of claim 1, wherein the first differential amplification element comprises:
a first transistor having a first terminal coupled to a first output of the first circuit, a second terminal coupled to the first adjustable source degeneration element, and a third terminal configured to receive a reference voltage; and
a second transistor having a first terminal coupled to a second output of the first circuit, a second terminal coupled to the first adjustable source degeneration element, and a third terminal configured to receive an input signal.

3. The device of claim 2, wherein the second differential amplification element comprises:
a third transistor having a first terminal coupled to the first output of the first circuit, a second terminal coupled to the second adjustable source degeneration element, and a third terminal coupled to the second output of the first circuit; and
a fourth transistor having a first terminal coupled to the second output of the first circuit, a second terminal coupled to the second adjustable source degeneration element, and a third terminal coupled to the first output of the first circuit.

4. The device of claim 3, wherein the second circuit further comprises:
a fifth transistor having a first terminal coupled to the second adjustable source degeneration element, a second terminal configured to receive a ground voltage, and a third terminal configured to receive a bias voltage; and
a sixth transistor having a first terminal coupled to the second adjustable source degeneration element, a second terminal configured to receive the ground voltage, and a third terminal configured to receive the bias voltage.

5. The device of claim 4, wherein the first circuit further comprises:
a seventh transistor having a first terminal coupled to the first adjustable source degeneration element, a second terminal configured to receive the ground voltage, and a third terminal configured to receive the bias voltage; and
an eighth transistor having a first terminal coupled to the first adjustable source degeneration element, a second terminal configured to receive the ground voltage, and a third terminal configured to receive the bias voltage.

6. (canceled)

7. The device of claim 1, wherein the second differential amplification element comprises:
a first transistor coupled to each of a first output of the first circuit, the second adjustable source degeneration element, and a second output of the first circuit; and
a second transistor coupled to each of the second output of the first circuit, the second adjustable source degeneration element, and the first output of the first circuit.

8. The device of claim 7, wherein a drain of the first transistor is coupled to the first output of the first circuit, a gate of the first transistor is coupled to the second output of the first circuit, a drain of the second transistor is coupled to the second output of the first circuit, and a gate of the second transistor is coupled to the first output of the first circuit.

9. A system, comprising:
a first adjustable stage including a first amplification stage coupled to a first source degeneration element; and
a second adjustable stage including second amplification stage coupled to a second source degeneration element, the second amplification stage having a first input and a second input, each of the first input and the second input of the second amplification stage coupled to each of a first output and a second output of a differential output of the first adjustable stage, each of the first source degeneration element and the second source degeneration element including a variable resistor coupled in parallel with a variable capacitor.

10. The system of claim 9, wherein:
the first input of second amplification stage comprises a first transistor having a first terminal coupled to the first output of the differential output of the first adjustable stage, a second terminal coupled to the second source degeneration element, and a third terminal coupled to the second output of the differential output of the first adjustable stage; and
the second input of the second amplification stage comprises a second transistor having a first terminal coupled to the second output of the differential output of the first adjustable stage, a second terminal coupled to the second source degeneration element, and a third terminal coupled to the first output of the differential output of the first adjustable stage.

11. The system of claim 10, wherein the second adjustable stage further comprises:
a third transistor having a first terminal coupled to the second source degeneration element, a second terminal configured to couple to a ground voltage, and a third terminal configured to couple to a bias voltage; and
a fourth transistor having a first terminal coupled to the second source degeneration element, a second terminal configured to couple to the ground voltage, and a third terminal configured to couple to the bias voltage.

12. The system of claim 10, wherein the first amplification stage comprises:
a third transistor having a first terminal coupled to the first output of the differential output of the first adjustable stage, a second terminal coupled to the first source degeneration element, and a third terminal configured to couple to a reference voltage; and
a fourth transistor having a first terminal coupled to the second output of the differential output of the first adjustable stage, a second terminal coupled to the first source degeneration element, and a third terminal configured to couple to an input voltage.

13. The system of claim 12, wherein the first adjustable stage further comprises:
a fifth transistor having a first terminal coupled to the first source degeneration element, a second terminal configured to couple to a ground voltage, and a third terminal configured to couple to a bias voltage; and
an sixth transistor having a first terminal coupled to the first source degeneration element, a second terminal configured to couple to the ground voltage, and a third terminal configured to couple to the bias voltage.

14. The system of claim 9, further comprising an input buffer including the first adjustable stage and the second adjustable stage.

15. A system, comprising:
at least one input device;
at least one output device;
at least one processor device operably coupled to the input device and the output device; and
at least one memory device operably coupled to the at least one processor device and comprising:
at least one input buffer, the at least one input buffer comprising:
a first stage including a first amplification stage coupled to a first source degeneration element; and
a second stage including second amplification stage coupled to a second source degeneration element, the second amplification stage comprising:
a first transistor having a first terminal coupled to a first output of the first stage, a second terminal coupled to the second source degeneration element, and a third terminal coupled to a second output of the first stage; and
a second transistor having a first terminal coupled to the second output of the first stage, a second terminal coupled to the second source degeneration element, and a third terminal coupled to the first output of the first stage, the second source degeneration element comprising: a variable resistor coupled between the first transistor and the second transistor; and a variable capacitor coupled in parallel with the variable resistor.

16. The system of claim 15, wherein each of the first source degeneration element includes a variable resistor coupled in parallel with a variable capacitor.

17. (canceled)

18. The system of claim 15, wherein a gate of the first transistor of the second amplification stage is coupled to a second output of the first stage, and a gate of the second transistor of the second amplification stage is coupled to a first output of the first stage.

19. The system of claim 18, wherein a drain of the first transistor of the second amplification stage is coupled to the first output of the first stage, and a drain of the second transistor of the second amplification stage is coupled to the second output of the first stage.

20. The system of claim 18, wherein the first stage comprises:
a third transistor having a gate configured to receive a reference voltage; and
a fourth transistor having a gate configured to receive an input received at the at least one input buffer.
